(19) United States
(12) Patent Application Publication
(10) Pub. No.: US 2006/0270229 A1
(43) Pub. Date: Nov. 30, 2006

(54) Anodized aluminum oxide nanoporous template and associated method of fabrication

(75) Inventors: Reed Roeder Corderman, Niskayuna, NY (US); Heather Diane Hudspeth, Clifton Park, NY (US); Renee Bushey Rohling, Burnt Hills, NY (US); Lauraine Denault, Nassau, NY (US); Scott Michael Miller, Clifton Park, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/141,613

(22) Filed: May 27, 2005

(51) Int. Cl. H01L 21/302; H01L 21/461

(52) U.S. Cl. 438/689; 438/719

(57) ABSTRACT

In some embodiments, the present invention is directed to nanoporous anodized aluminum oxide templates of high uniformity and methods for making same, wherein such templates lack a AAO barrier layer. In some or other embodiments, the present invention is directed to methods of electrodepositing nanorods in the nanopores of these templates. In still other embodiments, the present invention is directed to electrodepositing catalyst material in the nanopores of these templates and growing nanorods or other 1-dimensional nanostructures via chemical vapor deposition (CVD) or other techniques.

This invention was made with support from the United States Department of Commerce, National Institute of Standards and Technology (NIST) Contract No. 70NANB2H3030

### TECHNICAL FIELD

The present invention relates generally to nanoporous templates, and specifically to nanoporous templates of anodized aluminum oxide.

### BACKGROUND INFORMATION

An aluminum (Al) thin film may be anodized in acid to produce nanoporous anodized aluminum oxide (AAO) templates, where such templates comprise nanopores and are useful in the formation of nanorods (Masuda et al., Science, 1995, 268, p. 1466; and Masuda et al., Appl. Phys. Lett., 1997, 71, p. 2770; Jessensky et al., Appl. Phys. Lett., 1998, 72(10), p. 1173; Yin et al., Appl. Phys. Lett., 2001, 79, p. 1039; Zheng et al., Chem. Mater., 2001, 13, p. 3859). A consequence of this anodization process, however, is the production of a layer of aluminum oxide at the bottom of each nanopore (i.e., an AAO “barrier layer”) that inhibits electrical contact between the nanopores and the silicon (Si) wafer or other material the aluminum thin film resides upon.

Efforts to electrodeposit nanorods in these AAO nanopore templates (i.e., to form a nanorod/AAO array) have proved challenging because the AAO barrier layer must generally be removed before metal nanorod electrodeposition may be performed with good a real and height uniformity.

Several different methods to remove the AAO barrier layer have been reported in the scientific and patent literature, but these procedures do not give optimal results. For example, phosphoric acid (H₃PO₄) may be used to dissolve the AAO barrier layer (Chu et al., Chem. Mater. 2002, 14, p. 4595; Crouse et al., Appl. Phys. Lett. 2000, 76 (1), p. 49), but the AAO nanopores are isotropically widened as a result. That is, because H₃PO₄ etching is isotropic; not only is the AAO barrier layer dissolved, but also the pore walls are dissolved, and hence pore diameter increases. Subsequent nanorod electrodeposition then produces larger diameter nanorods. Also, H₃PO₄ etching may decrease the adhesion of the AAO to the Si wafer to the point where liftoff of the AAO from the Si wafer may occur. For many applications, smaller rather than larger diameter nanorods are required, so that the concomitant pore diameter increase from H₃PO₄ etching is inimical to these applications. For situations where planarization of a nanorod structure is required through the application of chemical-mechanical planarization (CMP), then any decrease in the adhesion of the nanorod/AAO array to the Si-wafer is also undesirable.

When the anodization of an Al thin film is complete, the Al metal initially present is completely consumed and the anodization current drops. If the anodization voltage is reduced in a stepwise manner, small dendrite pores can form in the barrier layer and permit pulsed electrodeposition of nickel (Ni) and cobalt (Co) nanowire arrays (Nielsch et al., Appl. Phys. Lett. 2001, 79 (9), p. 1360; Nielsch et al., Adv. Mater. 2000, 12 (8), p. 582). Such anodization voltage reduction and other electrochemical methods to remove the barrier layer have also been described. See Govyadinov et al., J. Vac. Sci. Technol. B 1998, 16 (3), p. 1222; Yuan et al., Appl. Phys. Lett. 2001, 78 (20) p. 3127; Saito et al., Appl. Phys. Lett. 1989, 55, p. 607; Jeong et al., Chem. Mater. 2002, 14, p. 1859; Jeong et al., Chem. Mater. 2002, 14 (10) p. 4003; and Forrer et al., J. Appl. Electrochem. 2000, 30, p. 533. Such methods have a significant drawback, however, in that the nanopore diameter gets larger with each reduction in voltage. This can compromise substrate adhesion, which, as mentioned above, has implications for processing techniques such as CMP.

An interface layer of niobium (Nb) may be placed between the Si wafer and the Al. Nb is anodized to insulating Nb₂O₅ and reduced in hydrogen (H₂) at 500° C. for 2 hours to yield partially conducting NbO₂. See Iwasaki et al., Appl. Phys. Lett. 1999, 75 (14), p. 2044; Jeong et al., Appl. Phys. Lett. 2001, 78 (14), p. 2052. The partially conducting NbO₂ interface, however, has a resistivity significantly higher than that of, for example, a Au interface layer. Subsequent nanowire electrodeposition on an NbO₂ interface gives mixed results. For example, while Ni nanowires may be electrodeposited on NbO₂, platinum (Pt) nanowire electrodeposition on an NbO₂ interface layer is extremely difficult. Even in the case of Ni nanorods, the fill factor (i.e., the ratio of the number of filled nanopores to total number of nanopores, expressed as a percent) is only about 40-50%, likely due to the high NbO₂ resistivity. Moreover, the high NbO₂ resistivity contributes to undesirable contact resistance between the nanowires and the Si substrate, a critical consideration in most electronic device applications.

A thin (e.g., 20 nm) interface layer of gold (Au) may be used between a substrate and the Al layer. See Yang et al., Solid State Commun. 2002, 123, p. 279. However, during anodization, a distribution of nanopore lengths ensues due to slight variations in a) the Si wafer resistivity, b) differences in the contact resistance where the anodization power supply is connected to the Si-wafer, or c) temperature across the Si wafer, and the resulting nanoporous AAO template suffers from a lack of uniformity.

Recently, a group at Penn State has described a method to penetrate the AAO barrier layer and promote detachment of the AAO layer as a freestanding thin film, separate from the substrate. The method uses a thin layer of titanium (Ti) underneath the Al to be anodized, but does not rely on the improved conductivity that results between the AAO nanopore and any underlying metal conducting layer (e.g., Au) as a result of the presence of this Ti layer. See Tian et al., Nanoletters 2005; ASAP Article; DOI: 10.1021/n10501112.

As a result of the above-described limitations, a method of generating nanoporous AAO templates, with better size control and more uniformity, and which can be used to efficiently make nanorods (i.e., with high fill factor) via electrochemical deposition, would be very beneficial.

### BRIEF DESCRIPTION OF THE INVENTION

As mentioned in the background, anodization of an Al thin film in dilute acid produces a nanoporous anodized aluminum oxide (AAO) template, which may be used as a template for nanorod deposition and/or growth. At the bottom of each nanopore, however, an AAO barrier layer is produced which inhibits nanorod electrodeposition.

In some embodiments, the present invention is directed to methods that eliminate the AAO barrier layer, and which have significant advantages compared to previously reported methods. Such AAO barrier layer elimination results from the formation of a sacrificial barrier layer, the use of which, at least in some embodiments of the present invention, results in uniform Pt nanorod growth in a nanoporous anodized aluminum oxide template over large areas (e.g., 2.85 cm²) with a high fill factor (pores-filled/total-pores). Through control of the interface oxide layer thickness, the etch time, and the etch solution composition; the areal density of filled nanowires in the nanoporous anodized aluminum oxide template may be controlled. The height of, for example, Pt nanorods (aka nanowires) can also be controlled by the duration of the Pt electrodeposition.

The formation of uniform height, small diameter metal nanorods in a nanoporous AAO template on a conducting substrate and/or Si wafer is the starting point for the fabrication of nanorod field emitters, thermoelectric devices, field effect transistor (FET) devices, and other electronic devices through the integration of nanotechnology, electrochemical, and Si microfabrication techniques.

The foregoing has outlined rather broadly the features of the present invention in order that the detailed description of the invention that follows may be better understood. Additional features and advantages of the invention will be described hereinafter which form the subject of the claims of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 depicts a layered thin film material, in accordance with embodiments of the present invention;

FIG. 2 depicts, in stepwise fashion, production of nanoporous AAO templates, as well as filling of these templates via electrochemical deposition, in accordance with embodiments of the present invention;

FIG. 3 is a SEM-BSE top-view micrograph of a Si wafer/1 μm layer of Al after anodization in 0.3 M oxalic acid at 25° C. for 600 seconds (10 minutes), where nanoporosity is clearly visible, and where the surface texture is due to the small Al grains produced by sputtering of the 1 μm layer of Al on the Si wafer;

FIG. 4 shows the anodization potential (thick line, left scale) and current density (thin line, right scale) for a 340 second anodization in 0.3 M oxalic acid at 25° C. of a 1 μm Al layer sputter-deposited on a 100 mm (4 inch) diameter Si wafer;

FIG. 5 illustrates cyclic voltammetry of a Si-wafer/Ti/Au/Ti/AAO nanoelectrode before TiOₓ etching, where the cathodic current at −0.6V is <1×10⁻⁶ A, which inhibits nanorod electrodeposition;

FIG. 6 illustrates cyclic voltammetry of a Si-wafer/Ti/Au/Ti/AAO nanoelectrode after TiOₓ etching, where the cathodic current at −0.6V is about 3×10⁻³ A, which permits nanorod electrodeposition;

FIG. 7 is a cross-sectional SEM-SE photomicrograph that shows essentially 100% fill factor for Pt nanorods in an anodized aluminum oxide template, where a slight amount of Pt nanorod underfill in the nanoporous AAO template is observed (8.0 Coulombs, 3550 seconds, no pore widening);

FIG. 8 is a light micrograph (LM) top view of a 1.9 cm (0.75 inches) diameter AAO nanoporous template uniformly filled with Pt nanorods (8.0 Coulombs, 3550 seconds, no pore widening);

FIG. 9 depicts non-uniform anodization of Si-wafer/20 nm Au/Al, where the anodization current flows through the lower-resistance longer nanopores (A), for which the pore tip is close to the Au (Pt) layer, while no current flows through the shorter nanopores (B), which are separated from the Al by a thick AAO barrier layer; and

FIG. 10 depicts non-uniform Pt nanorod electrodeposition of Si-wafer/TiW 10 nm/Au 20 nm/AAO 1200 nm, where the non-uniform anodization results in non-uniform Pt nanorod electrodeposition (dark areas).

### DETAILED DESCRIPTION OF THE INVENTION

In some embodiments, the present invention is directed to nanoporous anodized aluminum oxide templates of high uniformity and methods for making same, wherein such templates lack a AAO barrier layer. In some or other embodiments, the present invention is directed to methods of electrodepositing nanorods in the nanopores of these templates to form nanorod arrays. In still other embodiments, the present invention is directed to electrodepositing catalyst material in the nanopores of these templates and growing nanorods or other 1-dimensional nanostructures via chemical vapor deposition (CVD) or other techniques.

In the following description, specific details are set forth such as specific quantities, sizes, etc. so as to provide a thorough understanding of embodiments of the present invention. However, it will be obvious to those skilled in the art that the present invention may be practiced without such specific details. In many cases, details concerning such considerations and the like have been omitted inasmuch as such details are not necessary to obtain a complete understanding of the present invention and are within the skills of persons of ordinary skill in the relevant art.

Referring to the drawings in general, it will be understood that the illustrations are for the purpose of describing a particular embodiment of the invention and are not intended to limit the invention thereto.

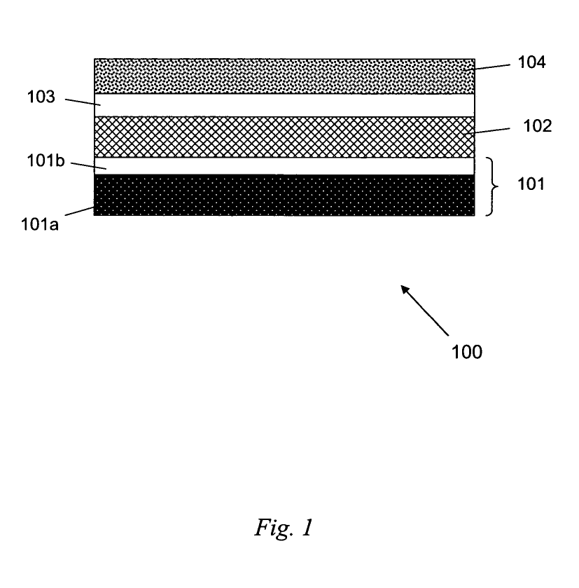

In some embodiments of the present invention, methods for making a nanoporous AAO template first require providing a layered thin film material. Referring to FIG. 1, layered thin film material 100 generally comprises: (a) a substrate 101, wherein the substrate may optionally comprise an adhesion layer 101b on top of a substrate base 101a; (b) a first metal (conductive) layer 102, wherein the first metal layer is electrically conductive, and wherein the first metal layer is not susceptible (i.e., is at least substantially immune) to anodization; (c) a second metal layer 103 on top of the first metal layer, wherein the second metal (conductive) layer comprises electrically-conducting metal other than Al, and wherein the second metal layer becomes insulating upon anodization; and (d) an Al thin film 104 on top of the second metal layer.

Referring to the layered thin film material above, the substrate can generally comprise any material. Exemplary materials include, but are not limited to, semiconductors, glasses, molecular solids, metals, ceramics, polymers, and combinations thereof. In some embodiments, the substrate is substantially smooth. “Substantially smooth” (aka “substantially flat”), as defined herein, is a surface smoothness sufficient to allow for reflection of visible light off the surface. In some embodiments, the substrate comprises a polished Si wafer.

In some embodiments, the substrate comprises an adhesion layer 101b. This optional adhesion layer can improve adhesion of the first metal layer 102 with the substrate. In some embodiments, the adhesion layer comprises Ti, but can generally be any thin layered material that adheres strongly to both the substrate base 101a and the first metal layer 102. In some embodiments, the thickness of this layer is important. In such embodiments, the thickness of this adhesion layer can be in the range of from at least about 5 nm to at most about several μm. In addition to Ti, a titanium-tungsten alloy (e.g., 10% Ti-90% W) or chromium (Cr) can be used.

Generally, the first metal layer 102 comprises any metal that is electrically-conductive and is not susceptible, or is only moderately susceptible, to anodization, i.e., it will not readily oxidize under the conditions of the anodization process—it is substantially immune to anodization. Suitable metals include, but are not limited to, gold (Au), silver (Ag), copper (Cu), platinum (Pt), palladium (Pd), nickel (Ni), ruthenium (Ru), rhodium (Rh), iridium (Ir), osmium (Os), and combinations thereof. In some or other embodiments, when the first metal layer 102 is moderately susceptible to anodization, any oxide formed in this layer can be removed or reduced prior to subsequent steps of electrodeposition. In some embodiments, the thickness of this first metal layer is important. In such embodiments, the thickness of this layer can be in the range of from at least about 10 nm to at most about 100 μm. In some embodiments, the first metal layer may be of some material other than metal, provided that it is at least semiconducting (e.g., Si). In some embodiments, the first metal (conductive) layer is simply a homogeneous extension of the substrate (e.g., a Si wafer).

The second metal layer 103 generally comprises any electrically-conducting metal other than Al, which becomes insulating upon anodization. Suitable metals include, but are not limited to, titanium (Ti), magnesium (Mg), niobium (Nb), tantalum (Ta), tungsten (W), zirconium (Zr), zinc (Zn), and combinations thereof. In some embodiments, the thickness of this second metal layer is important. In such embodiments, the thickness of this layer can be in the range of from at least about 5 nm to at most about 20 nm. In some embodiments, it is advantageous that this metal, once oxidized by an anodization process, be etchable under conditions that do not etch, or only slightly etch, AAO.

In some embodiments, the aluminum thin film 104 has a thickness in the range of from at least about 10 nm to at most about 300 μm. Understandably, the thickness of this Al film can have significant implications on nanopore depth in the corresponding nanoporous AAO template.

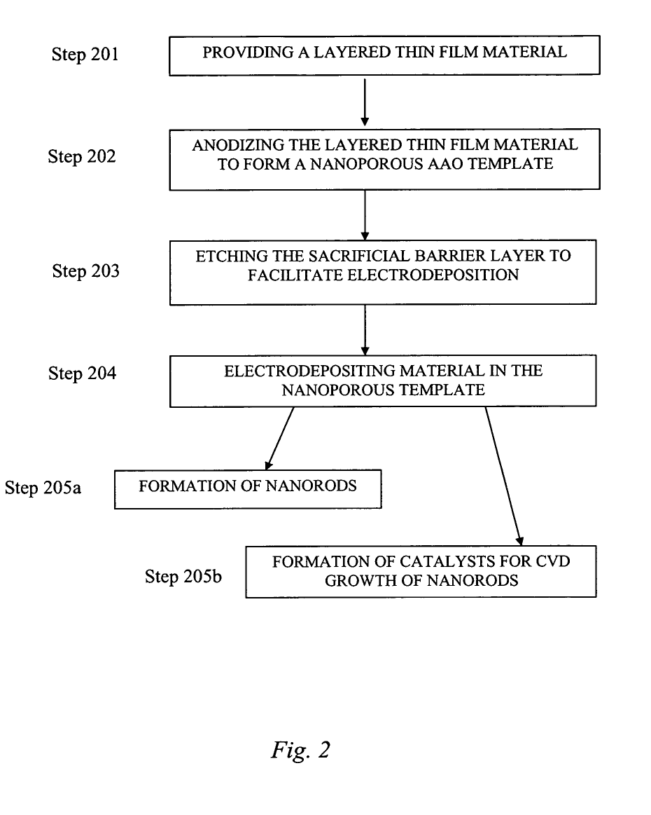

Referring to FIG. 2, in some embodiments, methods of making nanoporous AAO templates generally comprise the steps of: (Step 201) providing a layered thin film material (see above); (Step 202) anodizing the Al thin film (top layer of layered thin film material) to form a nanoporous AAO template residing on a sacrificial barrier layer (i.e., an insulating metal oxide barrier layer formed by the action of the anodization process on the second metal layer); and (Step 203) etching the sacrificial barrier layer to yield a nanoporous AAO template comprising nanopore channels (i.e., nanopores) that extend down to the first metal layer. Methods of using these nanoporous AAO templates typically further comprise a step of electrochemically-depositing material into the nanopores of the nanoporous AAO templates (Step 204). Such electrochemical deposition can lead to the formation of nanorods in the nanopores (Step 205a) or, when the deposition is minimal, can form catalysts at the nanopore bottom from which nanorods (or other 1-dimensional nanostructures) can be grown using chemical vapor deposition (CVD) or other techniques (Step 205b).

Techniques for anodizing Al metal to AAO are well-known in the scientific literature. See Keller et al., J. Electrochem. Soc., 1953, 100, p. 411; Kawai et al., J. Electrochem. Soc. 1975, 122, p. 32; Thompson et al., Nature, 1978, 272, p. 433; and Masuda et al., Science, 1995, 268, p. 1466. The step of anodizing generally comprises the sub-steps of: (a) contacting the layered thin film material with an electrolyte; (b) establishing an electrochemical cell, wherein the layered thin film material serves as an anode; and (c) applying a voltage to the electrochemical cell to electrochemically anodize anodizable layers of the layered thin film material and produce a nanoporous AAO template. Suitable electrolyte includes, but is not limited to, oxalic acid, sulfuric acid, phosphoric acid, citric acid, and combinations thereof.

The above-mentioned step of etching the sacrificial barrier layer (generated by the effect of the anodization process on the second metal layer) generally comprises immersing (or otherwise contacting) into an etching solution. Suitable etching solutions include any etching solution that can etch the insulating metal oxide (sacrificial barrier layer), but does not etch, or only slightly etches the AAO formed during the anodization process. Etching solutions found to be particularly useful for etching oxidized Ti (i.e., TiOₓ) comprise water (H₂O), hydrofluoric acid (HF), and hydrogen peroxide (H₂O₂). Compositional ranges for these solutions are 5:1:1 to 1000:1:1 H₂O: HF:H₂O₂ (where HF is 47-51% in water and H₂O₂ is 29-32% in water). In some embodiments, if wider nanopore diameters are desired, an etching step involving H₃PO₄ (or other suitable etchant) may be used before or after the forementioned TiO, etching step. Both NaOH and KOH also isotropically etch AAO and can also be used.

The resulting nanoporous AAO templates produced by the above-described methods typically have a high degree of uniformity in the nanopores. Depending upon the embodiment, the nanopore (channel) depth can be in a range from at least about 10 nm to at most about 300 nm, diameters (widths) of the nanopores can be in a range from at least about 10 nm to at most about 450 nm (after etching), and interpore spacing (i.e., the distance between nanopores) can be in the range of from at least about 20 nm to at most about 500 nm.

In some embodiments, nanorods are electrochemically-formed in the nanoporous AAO template (FIG. 2, Step 205a). Such nanorods can generally comprise any material that can be electrodeposited, i.e., metals, metal borides, carbides, nitrides, oxides, etc., subject only to the availability of a suitable electrolyte from which these materials may be electrodeposited. For many applications, Pt nanorods are particularly useful, and in corresponding embodiments the electrolyte comprises an electrodepositing solution comprising, for example, a commercially available platinum plating solution with 10 grams Pt/gallon (Technic, Inc., Cranston, R.I., product # 240651). In some embodiments, this plating solution comprises a Pt compound such as H₂PtCl₆. The fill factor (i.e., the ratio of filled nanopores to total number of nanopores, expressed as a percent) for such electrodeposition of nanorods can generally be in the range of from at least about 0.1% to at most about 100%. Controlled or tunable growth of nanorods is achievable by varying the thickness of the top interface layer (e.g., Ti) such that the fill factor can be modulated by this parameter. Additionally, the etch time and the etch solution composition (e.g., 5:1:1 H₂O:HF:H₂O₂ to 1000:1:1 can be modulated to further control the areal density of fill factor). Note that through control of the total cathodic charge during electrodeposition, the nanowire height can be controlled.

In some embodiments, material is electrochemically deposited in the wells of the nanopores to serve as a catalyst for the CVD growth of other nanorods (aka “nanowires”) and/or other 1-dimensional nanostructures. “1-dimensional nanostructures,” as defined herein, are nanoscale in exactly two dimensions, typically resulting in structures with high aspect ratios (e.g., length-to-width ratios of at least about 10). These nanostructures include, but are not limited to, nanotubes of carbon and other materials (e.g., born nitride), metal nanorods, and nanorods of nitrides, oxides, and carbides of a variety of materials. In some embodiments, the nanoporous AAO template assists in aligning these nanostructures as well as minimizing the contact resistance to the substrate, both critical aspects in many device applications. Alternatively, if the first metal layer and the catalyst are of the same material (e.g., Fe, Co, Ni, Au, etc.), then the step of electrochemically depositing a metal catalyst in the wells may be skipped, and chemical vapor-deposited 1-dimensional nanostructures can be grown in the nanopores directly from the first metal layer.

In some embodiments, the nanoporous AAO template is at least partially etched after deposition of nanorods into the nanopores. Such etching can be done using either a wet etching solution (e.g., buffered oxide etch (BOE), H₂O:HF:NH₄F, etc.) or dry etching (e.g., reactive ion etching, inductively-coupled plasma, etc.). Such etching can produce an aligned array of nanorods, with the tops of the nanorods exposed.

In some embodiments, the nanorods or other 1-dimensional nanostructures made in accordance with either Step 205a or Step 205b of FIG. 2 are subject to one or more post-synthesis processing steps. Such steps can include chemical-mechanical planarization (CMP), and/or other methods of planarization and/or processing. In some embodiments, the nanoporous AAO template is at least partially etched to expose the nanorods or other 1-dimensional nanostructures deposited or grown in the nanopores. In some embodiments, these nanorods or other 1-dimensional nanostructures are oriented substantially perpendicular to the substrate. “Substantially perpendicular,” as defined herein, means that the angle made between the substrate and the nanorods is at least 45°.

The nanorods or other 1-dimensional nanostructures, made according to the above-described embodiments, are operable for a wide variety of applications depending on their compositional make-up, dimensions, density, etc. The formation of uniform height, small diameter metal nanorods in a nanoporous AAO template on a conducting substrate and/or Si wafer can provide a starting point for the fabrication of nanorod field emitters, thermoelectric devices, field effect transistors, nanowire electrochemical electrodes, and other electronic devices through the integration of nanotechnology, electrochemical, and Si microfabrication techniques. Generally, methods of the present invention are broadly applicable to the fabrication of any electronic device for which a high electrical conductivity of nanowires (with respect to an underlying substrate) is desired. Such electronic devices include future nanorod transistor arrays such as those described by Ng et al. in Nano Lett. 2004, 4(7), p. 1247.

The following examples are included to demonstrate particular embodiments of the present invention. It should be appreciated by those of skill in the art that the methods disclosed in the examples that follow merely represent exemplary embodiments of the present invention. However, those of skill in the art should, in light of the present disclosure, appreciate that many changes can be made in the specific embodiments described and still obtain a like or similar result without departing from the spirit and scope of the present invention.

### EXAMPLE 1

This Example serves to illustrate the anodization of aluminum metal to AAO, in accordance with embodiments of the present invention.

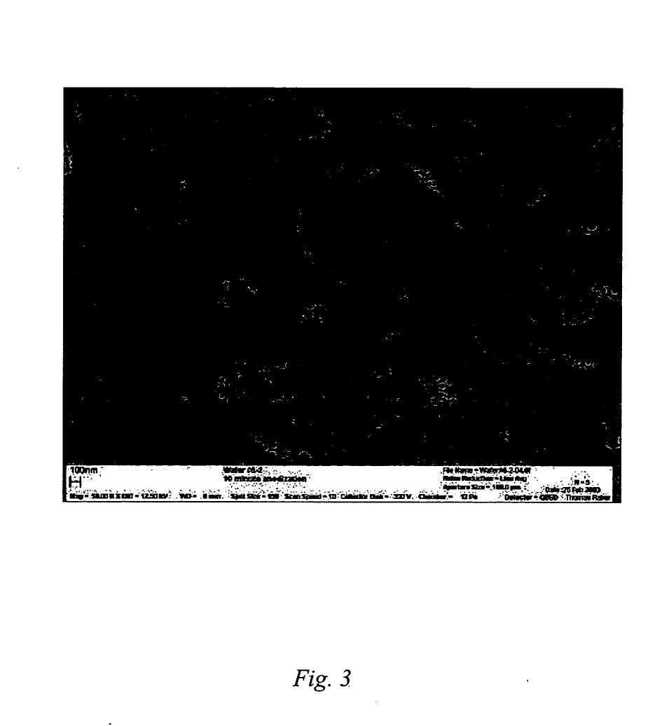

In a typical anodization, a 1 micrometer thick layer of Al was deposited onto the substrate by either sputtering or electron-beam evaporation. The Al-coated substrate was used as the anode in an electrochemical cell machined from polycarbonate. Approximately 12 mm distant from the Al-coated substrate, a 25×25 mm Pt-wire gauze (Alfa) was used as the counterelectrode. The electrochemical cell was filled with a solution of 0.3 Molar oxalic acid (C₂H₂O₄). Using a standard laboratory power supply (Agilent E3634A, 0-50 VDC, 0-4 A), the Al thin film was anodized at 25° C. for approximately 600 seconds with a constant voltage of 40 VDC and a current of about 8-12 mA/cm². After the anodization was complete (i.e., Al completely converted to AAO), the current drops to <0.001 mA/cm . The nanoporosity may then be studied by scanning electron microscopy (SEM). With the above conditions, the nanoporosity appears to be in the 40-60 nm diameter range, as shown in the SEM-derived image of FIG. 3.

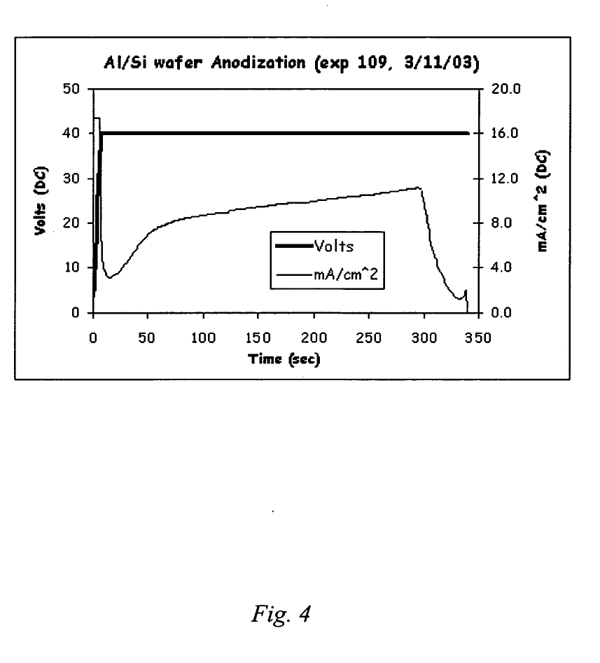

Computer control of the anodization power supply and measurement of the anodization potential and current were implemented. FIG. 4 shows the potential and current for the anodization of a 1 micrometer layer of Al on Si wafer. The anodization conditions are 0.3 M oxalic acid (C₂H₂O₄) at 25° C. for 340 seconds (about 6 minutes). After an initial transient, the anodization current slowly increases until the entire sputtered Al layer is consumed and a minimum current density of 1.27 mA/cm² is measured at 333 seconds. The anodization was stopped at 340 seconds.

### EXAMPLE 2

This Example serves to illustrate the anodization of layered thin film materials (i.e., several), along with their subsequent etching, to yield nanoporous AAO templates, in accordance with embodiments of the present invention.

Cleanroom produced wafers comprising a Si wafer base, a 20 nm Ti adhesion layer, a 50 nm Au (first metal) layer, a Ti (second metal) layer, and a 1000 nm Al layer. Wafers were produced having a Ti second metal layer thicknesses of 5, 10, 15, and 20 nm. Such wafers are denoted Si-wafer/20 nm Ti/50 nm Au/x nm Ti/1000 nm Al, where x is 5, 10, 15, and 20 nm. For each wafer, the Al was anodized until an insulating sacrificial barrier layer of TiOₓ was formed (the exact stoichiometry of the anodized Ti is unknown at present). As it is known that TiO₂ is etched by a solution of 20 H₂O:1 HF:1 H₂O₂ (by volume) at a rate of 880 nm/minute (Williams et al., J. MEMS 1996, 5 (4), p. 256; Williams et al., J. MEMS 2003, 12 (6), p. 761), the anodized wafers were subsequently dipped in etching solution (either 2:1 or 4:1 H₂O:TiO, etch, i.e., 40 H₂O:1 HF:1 H₂O₂ or 80 H₂O:1 HF:1 H₂O₂, respectively). The procedure used to etch the sacrificial TiOₓ barrier layer was to first determine the etch time to AAO liftoff (typically 60-90 seconds), and then to etch 15-30 seconds short of the liftoff time to remove the TiOₓ barrier layer.

### EXAMPLE 3

This Example serves to illustrate the subsequent electrodeposition of Pt into nanopores of a nanoporous AAO template to form Pt nanorods.

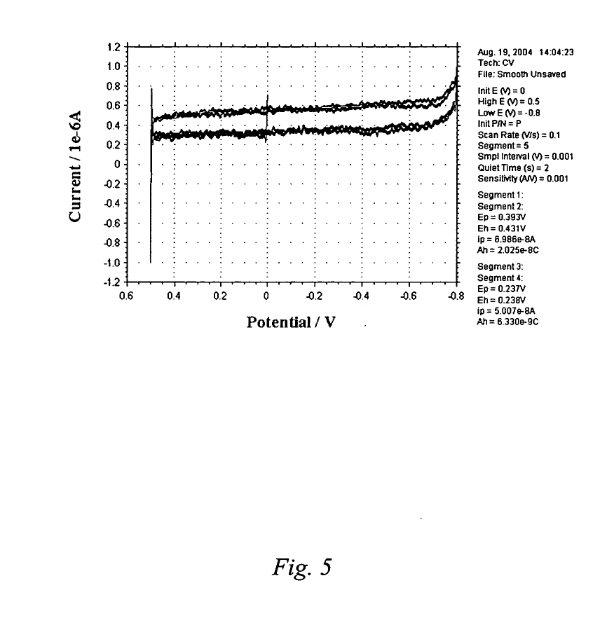

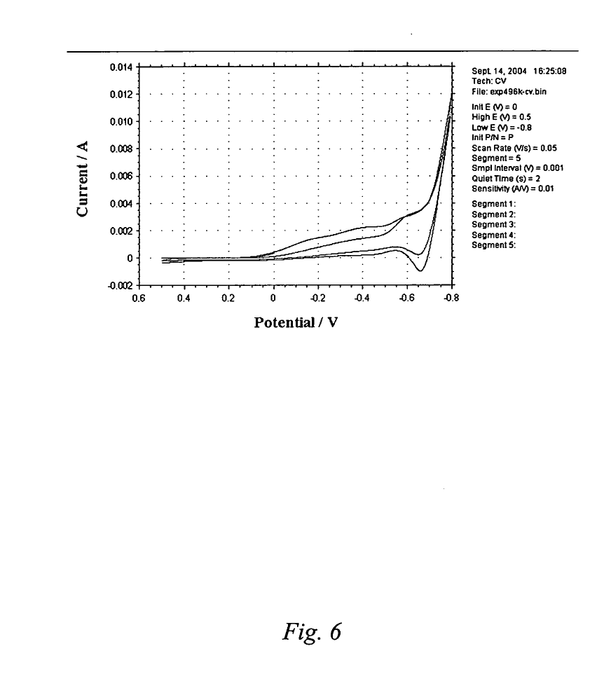

Cyclic voltammetry and Pt nanorod electrodeposition were used to characterize etched wafer samples and provide large area nanoporous AAO templates (0.75 inches in diameter), uniformly filled with Pt nanorods. The electrochemical procedures used a commercially-available 10 grams/gallon platinum plating solution (Technic, Inc., Cranston, R.I., product no. #240651); a layered thin film material denoted Si wafer/20 nm Ti/50 nm Au/10 nm TiOₓ/1200 nm AAO, and comprising a Si-wafer base (2.5 cm in diameter), a 20 nm Ti adhesion layer, a 50 nm Au (first metal layer), a 10 nm TiOₓ sacrificial barrier layer, and a 1200 nm AAO layer, wherein the layered thin film material serves as the working electrode; a 25×25 mm Pt wire gauze, 45 mesh, woven from 0.198 mm diameter wire (Alfa Aesar, stock #41814) serves as the counter electrode; and a Ag/AgCl (3M KCl) electrode serves as the reference electrode (CH Instruments, part no. CH111). A CH Instruments Model 660B electrochemical analyzer with CH Instruments electrochemical workstation version 4.05 software was used to control and record the electrochemical data. FIGS. 5 and 6 show the cyclic voltammetry of this electrochemical cell before and after the TiOₓ etch.

Before the TiOₓ etch, the current measured at −0.6 V (the potential at which the Pt nanorod growth is performed), is less than 1×10⁻⁶ A. After 30 seconds of TiOₓ etch, the current measured at −0.6 V is about 3 mA, which enables unifonn Pt—NR growth over the entire 1.9 cm (¾ in.) diameter.

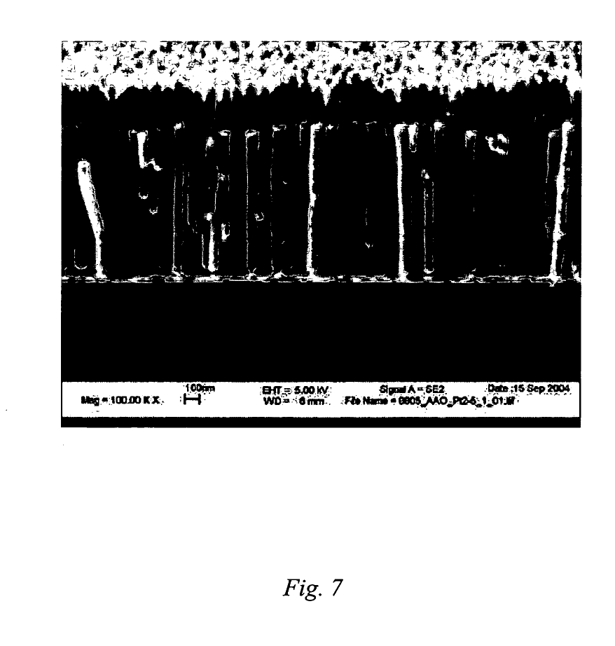

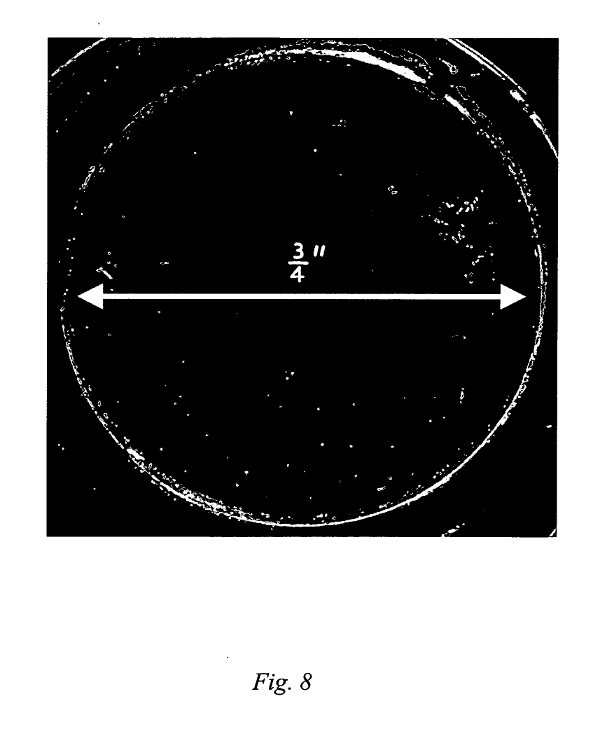

A cross section scanning electron microscope-secondary electron (SEM-SE) photomicrograph after electrodeposition showing essentially 100% fill factor for a Si-wafer/20 nm Ti/50 nm Au/10 nm Ti/AAO/1200 nm Pt nanorod sample is presented in FIG. 7. A top view light microscopy photomicrograph of the 1.9 cm (¾ in.) diameter nanoporous AAO template filled with Pt nanorods is presented in FIG. 8.

### EXAMPLE 4

This Example serves to illustrate the effect that the thickness of the second metal layer can play in determining the eventual fill factor realized in electrodepositing nanorods in the nanopores.

A design-of-experiments was performed to study the effect of top Ti layer thickness (second metal layer) on Pt nanorod electrodeposition. Four top Ti layer (second metal layer) thicknesses (5 nm, 10 nm, 15 nm, and 20 nm) were used in the fabrication of 2 each of 100 mm diameter Si wafers coated with an adhesion layer of Ti (20 nm), a 50 nm Au (first metal) layer, a Ti (second metal) layer, and a 1000 nm Al layer. While the 5 nm top Ti layer wafers produced about a 100% Pt nanorod fill factor, the 20 nm top Ti layer wafers produced significantly lower Pt nanorod fill factors of about 1-5%. The top Ti-layer thickness, TiOₓ etch time, and TiOₓ etchant composition may all be used to control (i.e., tune) the Pt nanorod fill factor.

### EXAMPLE 5

This Example serves to illustrate the effect of the composition of the first metal layer on the electrodeposition of Pt nanorods, in accordance with some embodiments of the present invention.

Wafers with a Cu conductive layer, i.e., Si-wafer/20 nm Ti/50 nm Cu/5 nm Ti/1000 nm Al, were fabricated. These wafers were then anodized, etched, and subjected to electrodeposition of Pt nanorods alongside similar wafers having a Au first metal layer. Preliminary results indicate that, at least in the production of Pt nanorods, a Cu first metal layer is better than Pt. Additionally, a Cu first metal layer is better than Au for two qualitative reasons. First, if the Pt-nanorod filled AAO samples are to be planarized, then Cu in the first metal layer is compatible with most cleanroom CMP tools, while Au is inimical to semiconductor performance and is typically disallowed in cleanroom CMP tools. Second, empirical observations in the FE-SEM suggest that in a sample with a Cu first metal layer, the Cu is in better electrical contact with the Pt-nanorods than a similarly produced sample with an Au first metal layer.

### EXAMPLE 6

This Example serves to illustrate how the TiOₓ etch rate can be modulated via modifying the concentration of the etching solution, and how these etches can be used in combination with isotropic etching, in accordance with some embodiments of the present invention.

Etch experiments using several different compositions of TiOₓ etch were used to slow the TiOₓ etch to a manageable time (about 30 seconds to 1 minute). The TiOₓ etch composition (i.e., etching solution) was initially 20:1:1 H₂O:BF:H₂O₂ (where HF is 47-51% (concentrated) and H₂O₂ is 29-32%). 40:1:1 and 80:1:1 TiOₓ etch compositions were also used. In several instances, isotropic pore widening, using 5% H₃PO₄, was applied to the anodized wafers before the TiOₓ etch was applied. The pore widening produced larger diameter nanopores, and hence larger diameter electrodeposited Pt nanorods.

### COMPARATIVE EXAMPLE 7

This comparative example serves to illustrate the non-uniformity of the nanopores in nanoporous AAO templates produced without a second metal layer (i.e., methods currently used in the art).

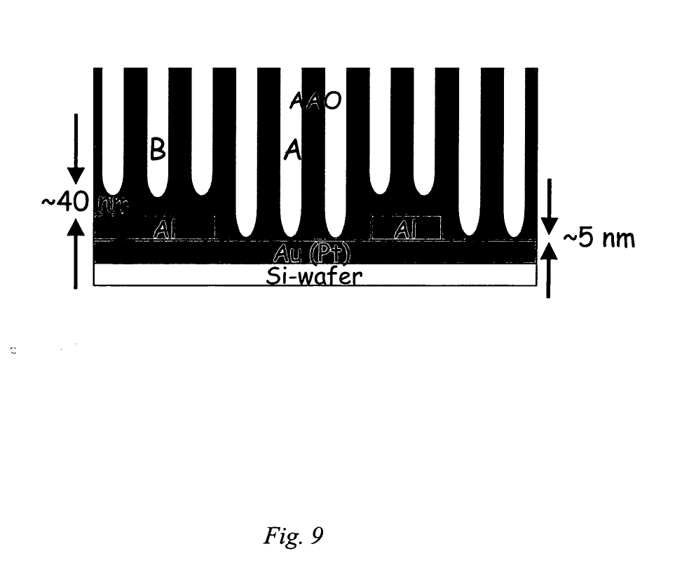

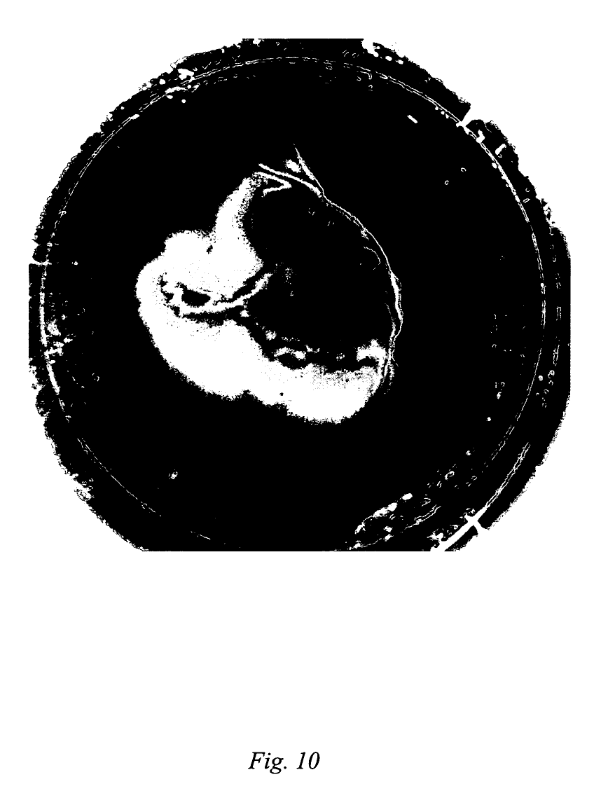

As described in the background, a thin (e.g., 20 nm) interface layer of gold may be used between a substrate and the Al layer. See Yang et al., Solid State Commun. 2002, 123, p. 279. However, during anodization, a distribution of nanopore lengths results due to slight variations in a) the Si wafer resistivity, b) differences in the contact resistance where the anodization power supply is connected to the Si wafer, or c) temperature across the Si wafer. This is shown schematically in FIG. 9. Referring to FIG. 9, when the longer nanopores (A) approach within several nanometers of a conducting interface layer, then all of the anodization current flows through this low resistance path. The anodization current to the shorter nanopores (B) then drops to approximately zero, residual Al remains unanodized, and the anodization becomes non-uniform over a large area (several cm²). As a result of the non-uniform or incomplete anodization, non-uniform Pt nanorod electrodeposition is observed, as in FIG. 10.

It will be understood that certain of the above-described structures, functions, and operations of the above-described embodiments are not necessary to practice the present invention and are included in the description simply for completeness of an exemplary embodiment or embodiments. In addition, it will be understood that specific structures, functions, and operations set forth in the above-described referenced patents and publications can be practiced in conjunction with the present invention, but they are not essential to its practice. It is therefore to be understood that the invention may be practiced otherwise than as specifically described without actually departing from the spirit and scope of the present invention as defined by the appended claims.

1. A method comprising the steps of:
a) providing a layered thin film material comprising:
i) a substrate;
ii) a first metal layer on top of the substrate, wherein the first metal layer is electrically conductive, and wherein the first metal layer is at least substantially immune to anodization;
iii) a second metal layer on top of the first metal layer, wherein the second metal layer comprises electrically-conducting metal other than Al, and wherein the second metal layer becomes insulating upon anodization and serves as a sacrificial oxide barrier layer; and
iv) an Al thin film on top of the second metal layer;
b) anodizing the Al thin film and the second metal layer to form a nanoporous anodized aluminum oxide template residing on the sacrificial oxide barrier layer; and
c) etching the sacrificial barrier layer to yield a nanoporous anodized alumium oxide template comprising nanopore channels that extend down to the first metal layer.

2. The method of claim 1, wherein the first metal layer is a homogeneous extension of the substrate.

3. The method of claim 1, further comprising a step of electrochemically depositing nanorods in the nanopores of the nanoporous anodized aluminum oxide template.

4. The method of claim 3, further comprising etching the nanoporous anodized aluminum oxide template to yield an at least partially-exposed array of electrochemically deposited nanorods in contact with the first metal layer and oriented substantially perpendicular to the substrate.

5. The method of claim 1, further comprising a step of electrochemically depositing metal catalyst in the nanopores of the nanoporous anodized aluminum oxide template, wherein the metal catalyst is operable for growing 1-dimensional nanostructures when exposed to a feedstock gas under suitable conditions of temperature and pressure.

6. The method of claim 1, wherein the metal of the first metal layer serves as a metal catalyst that is operable for growing 1-dimensional nanostructures when exposed to a feedstock gas under suitable conditions of temperature and pressure.

7. The method of claim 1, wherein the substrate comprises material selected from the group consisting of semiconductor, glass, metal, polymer, and combinations thereof.

8. The method of claim 1, wherein the substrate comprises silicon.

9. The method of claim 1, wherein the substrate is substantially flat.

10. The method of claim 1, wherein the substrate comprises an adhesion layer to facilitate adhesion between the substrate and the first metal layer.

11. The method of claim 10, wherein the adhesion layer comprises Ti.

12. The method of claim 1, wherein the first metal layer comprises metal selected from the group consisting of Au, Ag, Pt, Pd, Cu, Rfu, Rh, Os, Ir, Ni, and combinations thereof.

13. The method of claim 1, wherein the first metal layer comprises Au.

14. The method of claim 1, wherein the second metal layer comprises metal selected from the group consisting of Ti, Mg, Nb, Ta, W, Zr, Zn, and combinations thereof.

15. The method of claim 1, wherein the second metal layer comprises Ti.

16. The method of claim 1, wherein the step of anodizing comprises the sub-steps of:
a) contacting the layered thin film material with an electrolyte;
b) establishing an electrochemical cell, wherein the layered thin film material serves as an anode, and
c) applying a voltage to the electrochemical cell to electrochemically anodize anodizable layers of the layered thin film material and produce a nanoporous anodized aluminum oxide template comprising a the sacrificial oxide barrier layer.

17. The method of claim 16, wherein the electrolyte comprises an acid selected from the group consisting of oxalic acid, sulfuric acid, phosphoric acid, citric acid, and combinations thereof.

18. The method of claim 16, wherein the electrolyte comprises oxalic acid.

19. The method of claim 1, wherein the step of etching comprises exposing the nanoporous anodized aluminum oxide template residing on a sacrificial barrier layer to an, etching solution that is effective for etching the sacrificial barrier layer, but which is relatively unreactive with the anodized aluminum.

20. The method of claim 19, wherein the etching solution comprises H₂O, BF, and H₂O₂.

21. The method of claim 1 wherein the nanopore channels have post etching diameters from at least about 10 nm to at most about 450 nm.

22. The method of claim 1, wherein the nanopore channels have an average interpore distance of from at least about 20 nm to at most about 500 nM.

23. The method of claim 3, wherein the step of electrochemically depositing nanorods comprises the sub-steps of:
a) immersing the nanoporous anodized aluminum oxide template in an electrodepositing solution;
b) establishing an electrochemical cell wherein the nanoporous template and first metal layer serves as a working electrode; and
c) applying a voltage to the electrochemical cell such that material is deposited into the nanopores to yield nanorods.

24. The method of claim 23, wherein the electrodepositing solution comprises dissolved ions operable for being reduced and deposited on the cathode during the passage of electrical current through the electrochemical cell.

25. The method of claim 23, wherein the electrodepositing solution comprises H₂PtCl₆.

26. The method of claim 3, wherein the nanorods comprise post-etching diameters ranging from at least about 10 nm to at most about 450 nm.

27. The method of claim 3, wherein the nanorods are electrodeposited with a fill factor ranging from at least about 0.1% to at most about 100%.

28. The method of claim 27, wherein the fill factor is tunable.

29. The method of claim 4, wherein the anodized aluminum oxide is etched away using an etching solution selected from the group consisting of H₃PO₄, H₂SO₄, HF, BOE, KOH, NaOH, and combinations thereof.

30. The method of claim 4, wherein the anodized aluminum oxide is etched away using a dry etching technique.

31. The method of claim 5, wherein the 1-dimensional nanostructures are in a form selected from the group consisting of nanotubes, nanowires, nanorods, and combinations thereof; and wherein the 1-dimensional nanostructures comprise material selected from the group consisting of carbon; nitrides, borides, carbides, and oxides of metals, boron, and silicon; and combinations thereof.

32. A method comprising the steps of:
a) providing a layered thin film material comprising:
i) a substrate base;
ii) an adhesion layer on top of the substrate base;
iii) a first metal layer on top of the adhesion layer, wherein the first metal layer is electrically~conductive, and wherein the first metal layer is at least substantially immune to anodization;
iv) a second metal layer on top of the first metal layer, wherein the second metal layer comprises Ti, and wherein the second metal layer forms a sacrificial barrier layer comprising TiOₓ upon anodization; and
v) an Al thin film on top of the second metal layer;
b) anodizing the Al thin film and the second metal layer to form a nanoporous anodized aluminum oxide template residing on the sacrificial barrier layer; and
c) etching the sacrificial barrier layer to yield a nanoporous anodized aluminum oxide template comprising nanopore channels that extend down to the first metal layer.

33. The method of claim 32, further comprising a step of electrochemically depositing Pt nanorods in the nanopores of the nanoporous anodized aluminum oxide template.

34. The method of claim 33, wherein the electrode position of Pt nanorods in the nanopores is tunable.

35. The method of claim 34, further comprising an etching step to at least partially remove the anodized aluminum oxide template and yield at least partially exposed nanorods oriented substantially perpendicular on a substrate.

36. The method of claim 32, wherein electrode position is used to deposit catalyst material for subsequent CVD growth of 1-dimensional nanostractures.

37. A method comprising the steps of:
a) providing a layered thin film material comprising a substrate-supported layer of aluminum on top of a titanium layer;
b) anodizing the aluminum layer and the titanium, layer to form a nanoporous anodized aluminum oxide template residing on a TiOₓ sacrificial barrier layer; and
c) etching the TiOₓ sacrificial barrier layer to yield a nanoporous anodized aluminum oxide template comprising nanopore channels that extend down through the TiOₓ sacrificial barrier layer.

38. The method of claim 37 further comprising a step of electrochemically depositing nanorods in the nanopores of the nanoporous anodized aluminum oxide template.

39. The method of claim 37, further comprising etching the nanoporous anodized aluminum oxide template to yield an at least partially-exposed array of electrochemically-deposited nanorods in contact with the first metal layer and oriented substantially perpendicular to the substrate.

40. The method of claim 37, further comprising a step of electrochemically depositing metal catalyst in the nanopores of the nanoporous anodized aluminum oxide template, wherein the metal catalyst is operable for growing 1-dimensional nanostructures when exposed to a feedstock gas under suitable conditions of temperature and pressure.
